(19) United States
(12) Patent Application Publication
(10) Pub. No.: US 2002/0158781 A1
(43) Pub. Date: Oct. 31, 2002

(54) Coding a data stream

(76) Inventors: Maria Giuseppina Martini, Perugia (IT); Marco Chiani, Rimini (IT)

Correspondence Address: Philips Electronics North America Corporation, Corporate Patent Counsel, 580 White Plains Road, Tarrytown, NY, 10591, US

(21) Appl. No.: 10/070,867

(22) PCT Filed: Jul. 16, 2001
(86) PCT No.: PCT/EP01/08158

(30) Foreign Application Priority Data
Jul. 17, 2000 (EP) 00202530.2

(51) Int. Cl. H03M 7/00

(52) U.S. Cl. 341/59

(57) ABSTRACT

Coding a data stream comprising: channel coding (11) respective partitions of a given part of the data stream with different error protection rates to obtain a coded data stream (WS1), and including (20, 14) length information (lf) concerning respective lengths of the respective partitions in the coded data stream (WS1).

The invention relates to coding and decoding of a data stream.

The invention further relates to transmission and reception of a data stream.

Reference is made to the article of M. Budagavi, W. Rabiner Heinzelman, J. Webb, R. Talluri, “Wireless MPEG-4 Video Communication on DSP Chips”, IEEE Signal Processing Magazine, January 2000. This article discloses that, to make the compressed bit-stream more robust, the MPEG-4 video compression standard incorporates several error resilience tools in its simple profile to enable detection, containment, and concealment of errors. These are powerful source-coding techniques for combating bit errors when they occur at rates less than 10⁻³; however, present-day wireless channels can have much higher bit error rates (BERs). The harsh conditions on mobile wireless channels result from multipath fading due to motion between the transmitter and the receiver, and changes in the surrounding terrain. Multipath fading manifests itself in the form of long bursts of errors. Hence, some form of interleaving and channel coding is required to improve the channel conditions. Using a combination of source and channel coding, it is possible to achieve acceptable visual quality over error-prone wireless channels with MPEG-4 simple-profile video compression. The structure of an MPEG-4 compressed bit-stream also lends itself to using unequal error protection, a form of joint source-channel coding, to ensure fewer errors in the important portions of the bitstream.

An object of the invention is to provide an improved error protection of a data stream. To this end, the invention provides coding, decoding, transmission, reception, a coded data stream and a storage medium as defined in the independent claims. Advantageous embodiments are defined in the dependent claims.

The invention is based on the insight that in a coding scheme like MPEG-4, packets are not exactly of the same length and partitions have different lengths in different packets, due to the variable length coding used and to the requirement of having an integer number of macro-blocks in each packet. This implies that a fixed UEP scheme cannot be used and, in order to perform decoding with the correct code rate, the bit-stream structure should be known at the receiver, at channel decoding level. Packets, like partitions, are not of the same length; thus the UEP scheme should be dynamically changed for each packet and the knowledge of the partition length is required. This problem is addressed by including in the data stream, information about the lengths of the partitions that are or have been protected, e.g. in the form of a length field. Such a length field may be added in each packet after the resync marker. At the receiver side, the length information is read. UEP channel decoding may then be performed with the knowledge of the length of each partition.

Preferably, a specific, strong error protection is chosen for the length field, as the information it contains is crucial for the subsequent decoding.

Preferably, the length field may comprise the lengths of the packet partitions after channel encoding (i.e. the lengths of the channel-encoded partitions). This is advantageous because these are the lengths of the packet partitions furnished to the channel decoder.

Alternatively, the length field may contain the lengths of the packet partitions before channel coding. An advantage of including the lengths before channel encoding is that these lengths are shorter than the lengths after channel encoding, and can thus be more efficiently represented. Combining the lengths of the partitions before channel coding with the error protection rates results in the lengths of the channel-encoded partitions which are used in the channel decoder.

In practical embodiments, after the length information has been read, the length field is deleted from the bit-stream, i.e. it is not inserted in the bit-stream fed into a source decoder (e.g. an MPEG-4 decoder). This modification is therefore transparent to the source decoder.

The invention is especially advantageous in the field of wireless transmission of MPEG-4 video.

The aforementioned and other aspects of the invention will be apparent from and elucidated with reference to the embodiments described hereinafter.

In the drawings:

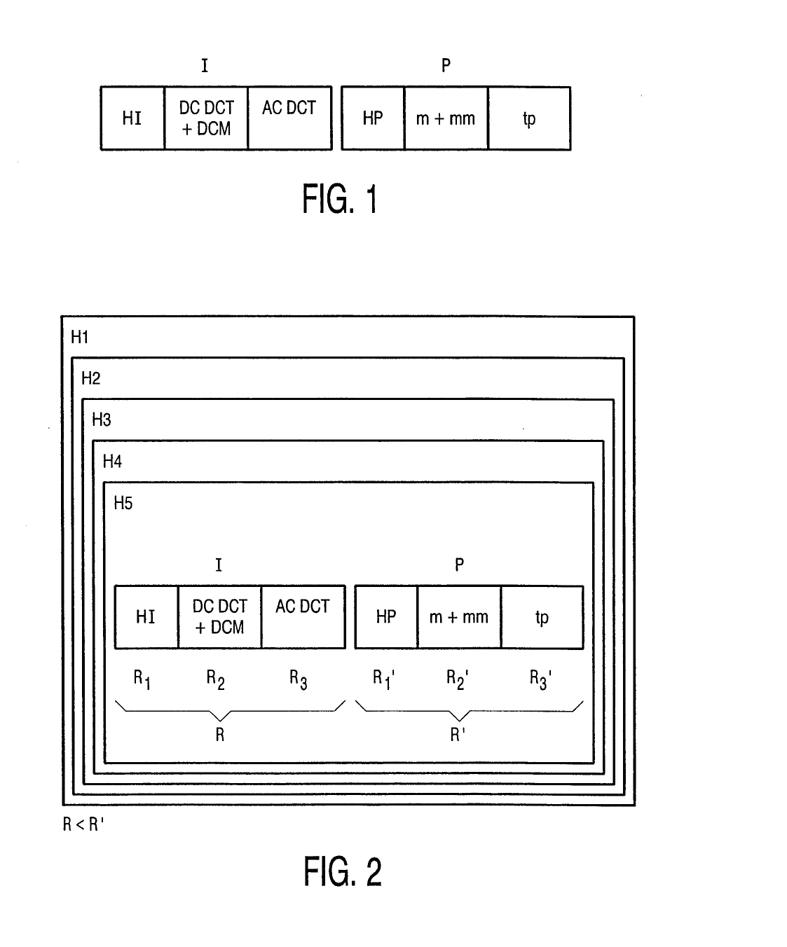

FIG. 1 shows data partitioning in the MPEG-4 bit-stream;

FIG. 2 shows a protection scheme in relation to an embodiment of the invention;

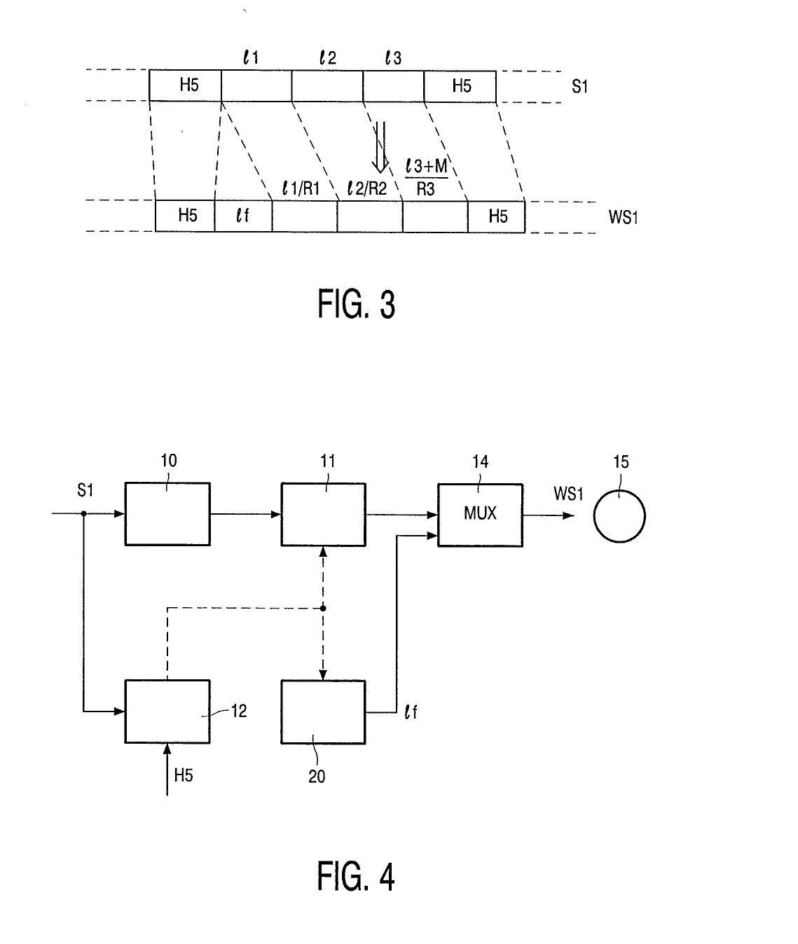

FIG. 3 shows unequal error protection and length field insertion according to an embodiment of the invention;

FIG. 4 shows unequal error protection and length field insertion combined with start code substitution according to an embodiment of the invention;

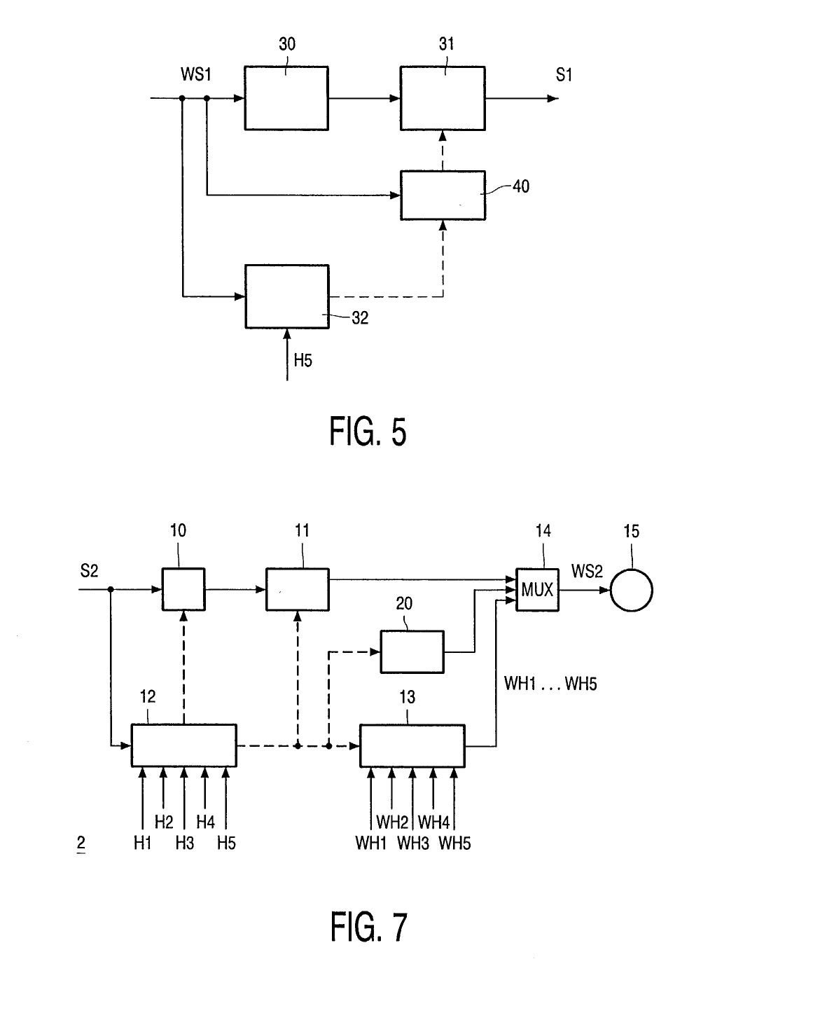

FIG. 5 shows a transmitter according to an embodiment of the invention, the transmitter comprising means for length field insertion;

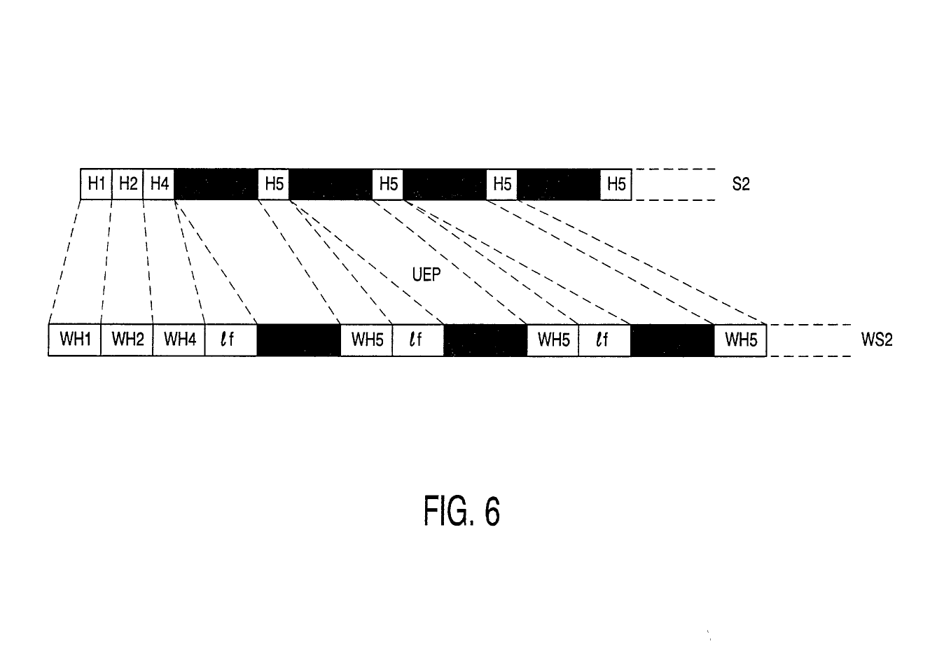

FIG. 6 shows a receiver according to an embodiment of the invention, the receiver comprising means for length field reading;

FIG. 7 shows a transmitter according to an embodiment of the invention, the transmitter comprising means for length field insertion, and means for start code detection and substitution; and

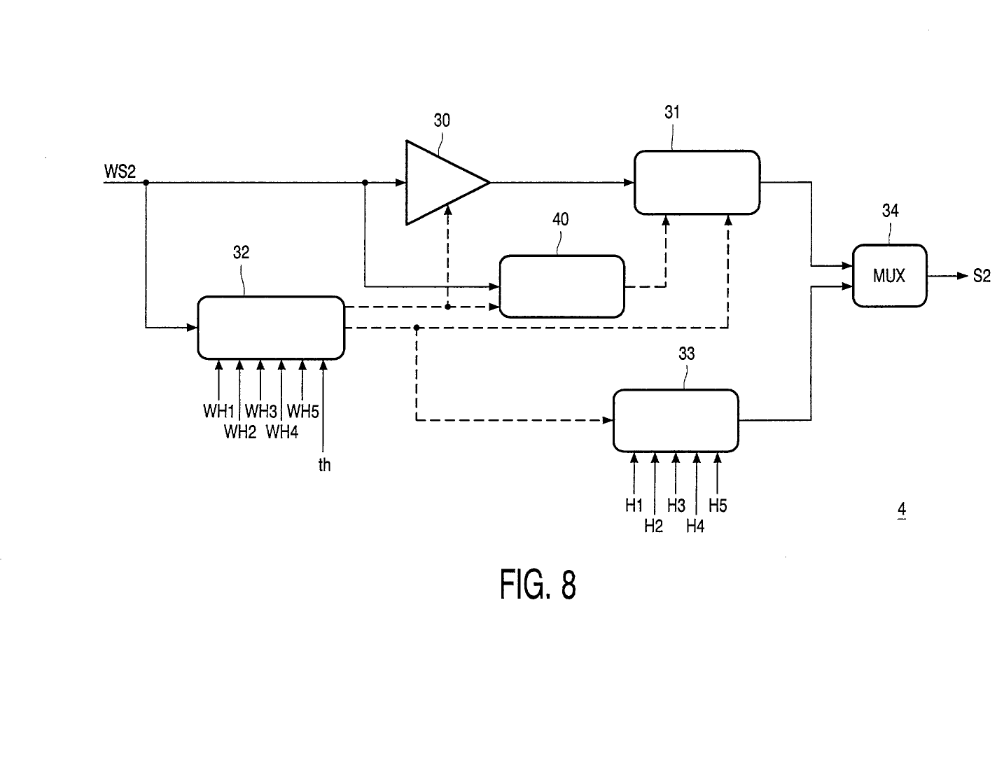

FIG. 8 shows a receiver according to an embodiment of the invention, the receiver comprising means for length field reading, and means for substituted start code detection and replacement.

Due to compression and in particular to the use of predictive coding and Variable Length Coding (VLC), an MPEG-4 bit-stream is very sensitive to errors. The article of R. Talluri, “Error-resilient video coding in the ISO MPEG-4 standard”, IEEE Communication Magazine, vol. 36, no.6, June 1998 describes error resilience aspects of the video coding techniques that are standardized in the ISO MPEG-4 standard. The specific tools adopted into the ISO MPEG-4 standard to enable the communication of compressed video data over noisy wireless channels are presented in detail. These techniques include resynchronization strategies, data partitioning, reversible Variable Length Codes, and header extension codes.

These tools help adding robustness to the MPEG-4 bit-stream. With the use of Resync markers, the MPEG-4 bit-stream results composed of packets, which are of almost the same length. Regardless of such tools, achievable received quality is still poor when MPEG-4 is transmitted over a wireless channel. Error resilience tools can, however, produce a further improvement of the received video quality if exploited at channel coding level. In particular, the data partitioning tool can be usefully exploited with the purpose of performing Unequal Error Protection (UEP): information bits contained in each packet are separated in three partitions, each of which has a different sensitivity to channel errors. As shown in FIG. 1 for I frames, partitions consist of a header HI, DC DCT coefficients and AC DCT coefficients separated by a DC marker DCM. As far as P frames are concerned, partitions consist of a header HP, and a motion partition m and a texture partition tp separated by a motion marker mm.

In the following, a suitable technique taking into account the characteristics of both the wireless channel and of the application is described in relation to an embodiment of the invention. Specifically, information about the different sensitivity of source bits to channel errors should be exploited through UEP. This technique consists in performing error protection according to the perceived sensitivity of source bits to errors: more sensitive bits are protected with a higher protection (corresponding to a lower rate code), for less important bits a lower protection (i.e. a higher rate code) is used. Compared to classical Forward Error Correction (FEC), UEP allows achieving a higher perceived video quality given the same bit-rate, through the exploitation of the characteristics of the source.

In the proposed scheme, the three partitions are protected with different code rates, according to the subjective importance of the relevant information. Information contained in headers is crucial for the successive decoding of the packet, thus those should be strongly protected. For intra frames, DC coefficients have a higher subjective importance than AC coefficients; thus the DC coefficients should be higher protected than the AC coefficients. As far as predicted frames are concerned, motion data should be more protected than texture data, as if motion information is correctly received texture information may be partially reconstructed.

The UEP implementation proposed takes also into account the different importance of different types of frames: in the MPEG-4 standard. Intra, Predicted and Backward predicted frames are considered, where Intra frames are coded independently from the others and Predicted frames exploit information from contiguous frames.

A correct reception of Intra frames is crucial to perform motion compensation of the subsequent Predicted frames, thus a lower average channel coding rate (i.e. a higher protection) could be associated to Intra frames, while Predicted frames can be coded with a higher average rate (i.e. a lower protection). FIG. 2 shows the described protection scheme.

An MPEG-4 coded bit-stream is structured in Video Objects (VO), Video Object Layers (VOL), Groups of Video Object Planes (GOV), Video Object Planes (VOP), and Packets. In order to allow synchronization, a start of each part of the bit-stream is indicated by a relevant start code. Start codes are unique words, recognizable from any legal sequence of variable length coded words. In FIG. 2, H1 indicates the start code for the VO, H2 the start code for the VOL, H3 the start code for the GOV, H4 the start code for the VOP and H5 the packet start code (resync marker).

UEP may be performed through Rate Compatible Punctured Convolutional (RCPC) codes, with rates chosen according to a perceived importance of bits. In this case the codes considered are obtained by puncturing the same “mother” code. Only one coder and one decoder are then needed for performing coding and decoding of the whole bit-stream. Rate Compatible Punctured Convolutional Codes as such are known from the article of J. Hagenauer, “Rate-Compatible Punctured Convolutional Codes (RCPC Codes) and their Applications”, IEEE Trans. Commun., vol.36, no.4, pp. 389-400, April 1988.

Different average code rates are taken into consideration for the protection of different frames (I frames are coded with a higher protection/ lower rate, a lower protection/higher average rate is taken into consideration for P frames), and for each frame the data partitioning tool added to the MPEG-4 standard is exploited, in order to provide a stronger protection for the most significant partitions.

FIG. 3 shows unequal error protection and length field insertion according to an embodiment of the invention. Information about the length of the partitions that are or have been protected is enclosed in the coded data stream, e.g. in a length field lf added in each packet after the resync marker H5. A specific, strong error protection is chosen for the length field, as the information it contains is crucial for the subsequent decoding. At the receiver side, after the detection of a resync marker, the length information is read (see FIG. 5). UEP channel decoding may then be performed with the knowledge of the length of each partition.

In this case, if l₁, l₂, l₃ are the lengths of the three partitions before channel encoding, the length of the coded packet including the length field will be:

$${L}_{coded\_packet} = \frac{{l}_{length\_field}}{{R}_{length\_field}} + \frac{{l}_{1}}{{R}_{1}} + \frac{{l}_{2}}{{R}_{2}} + \frac{{l}_{3} + M}{{R}_{3}}$$

where M is the memory of the code, in the case convolutional codes are considered.

As for the memory M of the code: convolutional codes differ from block codes in that the encoder contains memory and the encoder outputs at any given time unit not only depend on the inputs at that time unit, but also on M previous input blocks, where M is the memory of the code. A memory M convolutional encoder consists of an M-stage shift register with the output of selected stages being added modulo-2 to form the encoded symbols. Since a convolutional coder is a sequential circuit, its operation can be described by a state diagram. The state of the encoder is defined as its shift register contents; thus an encoder may assume 2^{M} states. In order to protect the last bits of the bit-stream with the same strength of the others, M tail bits should be added to the bit-stream in order to force the encoder to converge back to a known state (typically the “0” state). In fact, if convolutional codes are considered, the packet is terminated by shifting M “0” bits into the shift register in order to allow a proper termination of the trellis. Tail bits are coded with the higher rate. In order to compute the total average rate, the average between I frames and P frames should be computed and overhead (introduced by e.g. the length fields) should also be considered.

Preferably, the length field comprises the lengths of the packet partitions after channel encoding, i.e.

$$\frac{{l}_{1}}{{R}_{1}} , \frac{{l}_{2}}{{R}_{2}} , \frac{{l}_{3} + M}{{R}_{3}} ,$$

because these are the lengths of the packet partitions furnished to the channel decoder.

After the length information has been read, the length field is deleted from the bit-stream, i.e. it is not inserted in the bit-stream fed into the MPEG-4 decoder. As seen for the substitution of the original start codes with the “wireless” ones, also this modification is therefore transparent to the MPEG-4 decoder.

FIG. 4 shows a first transmitter according to an embodiment of the invention. A data stream S1 is received in a packet buffer 10. The first transmitter further comprises a start code detector for detecting resync markers H5 in the data stream S1. Packets of the data stream S1, present in between the markers H5, are channel encoded in a channel coder 11 to obtain channel coded packets. These channel coded packets are furnished to a multiplexer 14 and are included in a data stream WS1 to be transmitted. The transmitted data stream WS1 is furnished to an antenna, e.g. for wireless transmission, or to a storage medium 15. To perform length field insertion, the first transmitter comprises a length field insertion unit 20 that furnishes a length field lf to the multiplexer 14 which includes the length field in the transmitted data stream WS1 (see also FIG. 3). In this embodiment, the length field insertion unit 20 is controlled by the channel encoder 11 and/or the start code detection unit 12.

FIG. 5 shows a first receiver for receiving a data stream WS1 transmitted by an embodiment according to FIG. 4. If a resync marker H5 is detected in a start code detector 32, a packet buffer 30 is initialized and subsequent bits fill the buffer until the next start code is detected. When the next start code is detected, the buffer includes one packet. In a channel decoder 31, decoding is performed on the bits in the buffer, according to the VOP indicator information and to the length information included in the length field lf. The length field is detected and read in the length field detector 40. The rates used in the scheme are preferably fixed and the same as used in the channel coder. In the case of variable rates, the rates have to be received from the channel encoder in the transmitter. The channel-decoded packets form the channel decoded data stream S1 which is furnished to a source decoder (not shown), e.g. an MPEG-4 decoder. Note that if RCPC codes are used, de-puncturing is performed before decoding. In this case, the packet is then decoded at the mother code rate.

The length field insertion as described above is advantageously applied in combination with start code substitution. At channel coding level, an advantageous embodiment according to the invention is proposed, in which length field insertion is combined with start codes substitution. Start codes substitution addresses the problem that (MPEG-4) start codes are not robust to errors: a single error in a start code may cause missed detection, resulting in a loss of synchronization.

In start code substitution, at least one marker out of a predetermined set of at least two mutually different markers, the marker indicating a start of a given part of the data stream, is represented in the outputted data stream by a higher-robustness word having a higher robustness to channel errors than the at least one marker. The higher-robustness word may be a higher-robustness word with higher correlation properties than the respective marker, and is preferably a pseudo-noise word. Using higher-robustness words with higher correlation properties to represent markers makes transmission of these markers more robust against transmission errors. In a receiver, a given higher-robustness word is preferably detected by correlating the received data stream with higher-robustness words obtained from a predetermined set of higher-robustness words. If the correlation of the received data stream with a given higher-robustness word out of the predetermined set yields a value above a given threshold, the given higher-robustness word is decoded to obtain a corresponding marker at the position of the higher-robustness word. The higher-robustness word is preferably substituted by the corresponding ‘original’ marker. This has the advantage that ‘original’/unaffected markers are present in the MPEG-4 data stream at the receiver after channel decoding. This embodiment of the invention therefore provides advantageous error protection by transparent substitution of start codes with higher-robustness words.

Preferably, the data packets in the data stream are coded according to a channel coding mechanism different from spread-spectrum coding.

Advantageously, at the transmitter side, respective markers are substituted with respective higher-robustness words obtained from a predetermined set of higher-robustness words, each higher-robustness word in the set of higher-robustness words representing a given marker in the predetermined set of markers. By substituting the markers by a corresponding higher-robustness word, fast and advantageous coding is provided. The higher-robustness words can fast and easily be obtained from a look-up table. Coding errors that could be obtained when the markers are coded with a pseudo-noise sequence impressed on the marker are avoided.

Although substitution of the markers with respective new higher-robustness words obtained from a predetermined set of higher-robustness words is advantageous, the higher-robustness words with higher correlation properties may alternatively be obtained by impressing a fixed pseudo-noise sequence on the markers at a modulator. In this embodiment, it is possible in the decoder to obtain the original markers by removing the fixed pseudo-random sequence from the higher-robustness words at a demodulator.

John G. Proakis, ‘Digital communications’, 2^{nd} edition, McGraw-Hill, 1989, pp. 801-817 discloses spread-spectrum signals for digital communications. Spread-spectrum signals used for the transmission of digital information are distinguished by the characteristic that their bandwidth W is much greater than the information rate R in bits per second. That is, the bandwidth expansion factor Bₑ=W/R for a spread-spectrum signal is much greater than unity. The large redundancy inherent in spread-spectrum signals is required to overcome the severe levels of interference that are encountered in the transmission of digital information over some radio and satellite channels. Proakis discloses a spread-spectrum digital communications system with a binary information sequence at its input at the transmitting end and at its output at the receiving end. The channel encoder and decoder and the modulator and demodulator are basic elements. In addition to these elements, two identical pseudo-random pattern generators, one which interfaces with the modulator at the transmitting end and the second which interfaces with the demodulator at the receiving end. The generators generate a pseudo-random or pseudo-noise (PN) binary-valued sequence, which is impressed on the transmitted signal at the modulator and removed from the received signal at the demodulator. Synchronization of the PN sequence generated at the receiver with the PN sequence contained in the incoming received signal is required in order to demodulate the received signal. Initially, prior to the transmission of information, synchronization may be achieved by transmitting a fixed pseudo-random bit pattern, which the receiver will recognize in the presence of interference with a high probability. After time synchronization of the generator is established, the transmission of information may commence. Generation of PN sequences is further explained on pages 831-836.

In the following, advantageous embodiments are described for the simplified case of VOP's coincident with frames.

In the proposed scheme, start codes in a data stream S2 are substituted (see FIG. 6) with pseudo-noise words WH1 . . . WH5, which are sequences with high correlation properties (e.g. Gold sequences). These new start codes are denoted by Wireless Start Codes. In particular, a substitution is performed for VO, VOL, VOP, GOV start codes and for the Resync marker. The data stream in FIG. 6 does not include the GOV start code (H3), considering the MPEG-4 bit-stream. In the MPEG-4 bit-stream there is no GOV start code (H3) after the VOL start code (H2), because the VOL start code (H2) also indicates the beginning of a GOV.

At the receiver side, the position of these wireless start codes WH1 . . . WH5 are estimated through correlation before the channel decoding process; a trade-off should be achieved between the probability of missing a start code and the probability of start codes emulation, thus the choice of the wireless start codes length and of a proper threshold for the correlation is performed accordingly. As the detection is performed, wireless start codes WH1 . . . WH5 are substituted with the corresponding start codes H1 . . . H5 from an original set of start codes. The described substitution is herewith transparent to the source decoder.

FIG. 7 shows a second transmitter according to an embodiment of the invention, similar to the transmitter of FIG. 5, but arranged to further perform start codes substitution. In the second transmitter the start code detector 12 is arranged to detect the codes H1 . . . H5 in a data stream S2. A detected start code is substituted by a corresponding pseudo-noise word WH1 . . . WH5 by a pseudo-noise word generator 13. The pseudo-noise word is furnished to the multiplexer 14 that includes the pseudo-noise word in the data stream WS2 to be transmitted.

FIG. 8 shows a receiver for receiving a data stream WS2 transmitted by an embodiment similar to FIG. 7. In the start codes detector 32 (e.g. a pseudo-noise word detector), correlation evaluations are performed between each allowed pseudo-noise word (i.e. from the predetermined set of pseudo-noise words, corresponding to the markers) and the relevant bit-stream portion in order to detect pseudo-noise words representing start codes. Correlations are compared with corresponding thresholds th. When a pseudo-noise word is detected, the bit indicator in the bit-stream shifts the proper number of bits and the corresponding MPEG-4 start code H1 . . . H5 is provided by start code generator 33, which start code is inserted in a multiplexer 34 whose task is to arrange a bit-stream S' to be fed to the MPEG-4 decoder. If either a GOV start code or a VOP start code is detected, a VOP indicator changes its status.

Preferably, no correlation evaluation is performed until the buffer contains N bits, where N is the minimum length of a packet.

Although not shown in FIGS. 4-5, 7-8, the data stream may be modulated before transmission by a modulator in the transmitter and consequently be demodulated in the receiver by a demodulator before decoding is performed.

In the length field, instead of in absolute length values, the lengths of the respective packet partitions may also be given in percentages of the packet length.

In the case the respective lengths of the packet partitions remain constant over a multiple of (subsequent) packets, it suffices to include length information in one of these packets, e.g. a first packet. It is further possible to use differential lengths in a given length field, the differential lengths indicating differences between the current respective packet partition lengths and previous respective packet partition lengths.

Because some packet partitions are usually shorter than other packet partitions, the number of bits reserved in the length field for indicating the lengths of these usually shorter packet partitions is preferably less than the number of bits reserved for indicating the lengths of longer packet partitions. For example, the header of a packet is usually shorter than the other packet partitions. Therefore, the number of bits reserved in the length field to indicate the length of a header is preferably smaller than for other, longer packet partitions.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word ‘comprising’ does not exclude the presence of other elements or steps than those listed in a claim. The invention can be implemented by means of hardware comprising several distinct elements, and by means of a suitably programmed computer. In a device claim enumerating several means, several of these means can be embodied by one and the same item of hardware. The mere fact that certain measures are recited in mutually different dependent claims does not indicate that a combination of these measures cannot be used to advantage.

1. A method of coding a data stream (S1,S2), the method comprising:
channel coding (11) respective partitions of a given part of the data stream with different error protection rates to obtain a coded data stream (WS1, WS2), and
including (14, 20) length information (lf) concerning respective lengths of the respective partitions in the coded data stream (WS1, WS2).

2. A method as claimed in claim 1, wherein the length information (lf) comprises the lengths of the partitions before channel coding.

3. A method as claimed in claim 1, wherein the length information (lf) comprises the lengths of the partitions after channel coding.

4. A method as claimed in claim 1, wherein the length information (lf) is included in a field just after a resync marker (H5) of the given part of the data stream (S1, S2).

5. A method as claimed in claim 1, wherein the data stream (S1, S2) comprises at least one marker (H1 . . . H5) out of a predetermined set of at least two mutually different markers (H1 . . . H5), the marker indicating a start of a given part of the data stream, the method further comprising:
representing (13) the at least one marker (H1 . . . H5) with a higher robustness word (WH1 . . . WH5) having a higher robustness to channel errors than the at least one marker; and
outputting (14) the data stream with the at least one marker represented with the higher-robustness word (WH1 . . . WH5).

6. A method of decoding a coded data stream (WS1, WS2), in which coded data stream respective partitions of a given part of the coded data stream have been channel encoded with different error protection rates, the coded data stream further comprising length information (lf) concerning respective lengths of the respective partitions in the coded data stream, the method comprising:
reading (40) the length information (lf), and
channel decoding (31) the coded data stream (WS1, WS2) using the length information (lf) to obtain a decoded data stream (S1, S2).

7. A method as claimed in claim 6, the method further comprising:
deleting (40, 31, 34) the length information (lf) from the coded data stream.

8. An encoder for coding a data stream (S1, S2), the encoder comprising:
a channel encoder (11) for channel coding respective partitions of a given part of the data stream with different error protection rates to obtain a coded data stream (WS1, WS2), and
means (14, 20) for including length information (lf) concerning respective lengths of the respective partitions in the coded data stream (WS1, WS2).

9. A decoder for decoding a coded data stream (WS1, WS2), in which coded data stream respective partitions of a given part of the coded data stream have been channel encoded with different error protection rates, the coded data stream further comprising length information (lf) concerning respective lengths of the respective partitions in the coded data stream, the decoder comprising:
means (40) for reading the length information, and
means (31) for channel decoding the coded data stream (WS1, WS2) using the length information (lf) to obtain a decoded data stream (S1, S2).

10. A transmitter for transmitting a coded data stream (WS1, WS2), the transmitter comprising:
an encoder as claimed in claim 8; and
means (14) for transmitting the coded data stream (WS1, WS2).

11. A receiver for receiving a coded data stream (WS1, WS2), the receiver comprising:
means (30) for receiving the coded data stream; and
a decoder as claimed in claim 9;

12. A coded data stream (WS1, WS2) in which respective partitions of a given part of the coded data stream have been channel encoded with different error protection rates, the coded data stream further comprising length information (lf) concerning respective lengths of the respective partitions in the coded data stream

13. A storage medium (15) on which a coded data stream (WS1, WS2) as claimed in claim 12 has been stored.
